(19) United States
(12) Patent Application Publication
(10) Pub. No.: US 2014/0191212 A1
(43) Pub. Date: Jul. 10, 2014

(54) SUBSTRATE WITH AN ELECTRODE FOR AN OLED DEVICE AND SUCH AN OLED DEVICE

(71) Applicant: Fabien Lienhart, San Diego, CA (US)

(72) Inventor: Fabien Lienhart, San Diego, CA (US)

(73) Assignee: SAINT-GOBAIN GLASS FRANCE, Courbevoie (FR)

(21) Appl. No.: 14/126,733

(22) PCT Filed: Jun. 14, 2012
(86) PCT No.: PCT/FR2012/051336

§ 371 Date: Feb. 10, 2014

(30) Foreign Application Priority Data
Jun. 16, 2011 (FR) 1155269

(51) Int. Cl. H01L 51/52; H05K 1/09

(52) U.S. Cl. CPC H01L 51/5203; H05K 1/09
USPC 257/40; 174/257; 204/192.12

(57) ABSTRACT

A substrate carrying an OLED electrode, with a sheet resistance of less than 25 Ω/square, includes an electrically conducting coating, an essentially inorganic thin electrically conducting layer which is a work-function-matching layer and which exhibits a sheet resistance at least 20 times greater than the sheet resistance of the electrically conducting coating, with a thickness of at most 60 nm, and, between the electrically conducting coating and the work-function-matching layer, a thin buffer layer, which is essentially inorganic and which has a surface resistivity within a range from 10⁻⁶ to 1 Ω·cm².

The invention relates to the field of electrodes for organic light-emitting diode (OLED) devices.

The OLED comprises an organic light-emitting material or a stack of materials and is framed by two electrodes, one of the electrodes, referred to as lower electrode, generally the anode, being composed of this in combination with the substrate and the other electrode, referred to as upper electrode, generally the cathode, being arranged over the organic light-emitting system.

The OLED is a device which emits light by electroluminescence using the recombination energy of holes injected from the anode and of electrons injected from the cathode.

Different OLED configurations exist:
bottom emission devices, that is to say devices with a lower (semi)transparent electrode and an upper reflecting electrode (in this case, the substrate is directed toward the observer);
top emission devices, that is to say devices with an upper (semi)transparent electrode and a lower reflecting electrode;
top and bottom emission devices, that is to say devices with both a lower (semi)transparent electrode and an upper (semi)transparent electrode.

The invention relates to bottom and/or top emission OLED devices targeted at the lighting market.

Mention may be made, among the advantages of this OLED technology, of the light efficiency, the possibility of producing thin lighting surfaces and the flexibility.

Anodes based on ITO (mixed oxide of indium and tin) are known. They can be easily deposited by magnetic-field-assisted (magnetron-assisted) cathode sputtering. Their sheet resistance is of the order of 20 Ω/square. The ITO anodes are designated, in the continuation of the description, first-generation anode.

Furthermore, the document WO2009/083693 teaches anodes with stacks of thin layers with two silver-comprising layers between nonreflecting layers, the final electrically conducting layer being made of ITO with a thickness of less than or equal to 50 nm and exhibiting a work function appropriate for the injection of holes.

This last type of anodes described above is referred to as second-generation anode in the continuation of the description. The sheet resistance of the stack in these second-generation anodes is lower than those of the first generation.

The first- and second-generation anodes exhibit morphology defects, commonly known as “spikes”, due to the manufacturing tolerances. They are in particular defects of flatness of the surface of the substrate, or defects generated during the deposition and/or the growth of at least one of the thin layers (presence of dust, and the like), which result in spike effects when the OLED is operating. These spike effects cause short circuits with a high risk of overheating, which spike effects can damage the organic light-emitting components which interact with the electrode. This causes accelerated aging of some parts of the OLED and considerably shortens its lifetime.

Furthermore, visible defects appear on the OLED in operation.

An aim of the invention is to solve the abovementioned disadvantages by providing an anode, more broadly an electrode, for an OLED device, which is reliable, robust and capable of limiting the number of visible defects, without sacrificing its electrical conductivity properties, its optical qualities and the optical performance of the OLED, and without generating implementation difficulties.

Incidentally, it is matter of achieving this objective without disrupting the known configurations of the organic light-emitting systems relating to the invention.

It is a question of developing in particular an OLED device suitable very particularly in general (architectural and/or decorative) lighting applications, and/or backlighting applications, and/or identifying applications, and for any size.

To this end, a first aspect of the invention relates to a substrate carrying an electrode intended to form the anode or the cathode of an organic light-emitting diode, “OLED”, device, said electrode being based on an electrically conducting stack with a sheet resistance of less than 25 Ω/square, indeed even of less than or equal to 10 Ω/square, comprising:
an electrically conducting coating of thin layer(s) forming at least 90% of the electrical conduction of the stack,
an essentially inorganic thin electrically conducting layer which is a work-function-matching layer, designed to be placed in contact with an organic layer for injection of the charges of the OLED, the work-function-matching layer, with a thickness of at most 60 nm, exhibiting a sheet resistance at least 20 times greater than the sheet resistance of the electrically conducting coating.

The substrate additionally comprises, between the electrically conducting coating and the work-function-matching layer, a thin layer, referred to as buffer layer, which is essentially inorganic and which has a surface resistivity within a range from 10⁻⁶ to 1 Ω·cm².

The invention thus consists in incorporating a thin layer in the electrode in order:
to limit the current capable of being sent when the anode comes into contact with the cathode (once the organic part has incinerated, short-circuited),
and also to limit the spatial extension of the defect by bringing about a fall in voltage over a smaller spatial extension.

Such an arrangement of layers thus makes it possible to hide the falls in brightness (regions of shadows) which normally appear around the spikes and which testify to localized falls in voltages. Phenomena of short circuits with overheating which damage the OLED are also avoided and its lifetime is improved.

The buffer layer thus exhibits a carefully selected intermediate surface resistivity: the material is sufficiently electrically conducting not to excessively increase the series resistance of the OLED device in operation but sufficiently low in conduction to limit the current in the event of short circuit. The surface resistivity of the buffer layer is very particularly suitable for an OLED device for lighting involving high current densities (in particular at least a current density of 1 mA/cm²), in particular in order to achieve a luminance of at least 500 cd/m², indeed even of 1000 cd/m² and even of at least 3000 cd/m².

The electrode according to the invention can be over a large surface area, for example a surface area of greater than or equal to 0.002 m², indeed even 0.02 m², indeed even at least 0.5 m².

In addition, the inventors have demonstrated, unexpectedly, that it is not necessary to remove the inorganic work-function-matching layer, which would risk damaging the light efficiency of the OLED device, in order for the buffer layer to be effective but that it is, however, crucial even for a very thin work-function-matching layer, to impose on it a limiting sheet resistance which depends on that of the electrically conducting coating, this being in order to limit its lateral conduction.

Thus, contrary to the prior art, a work-function-matching layer is not chosen which is as electrically conducting as possible. In addition, it is not necessary to modify the existing organic charge carrier injection layer or layers (for example to dope them) as the light efficiency of the OLED is retained by the maintenance of the work-function-matching layer.

The buffer layer and the work-function-matching layer are distinct layers in order to separate the functionalities and to give flexibility.

The inorganic work-function-matching layer is the final inorganic layer of the electrode (electrode layer closest to the organic charge injection layer) and is preferably a monolayer.

The buffer layer is preferably in contact with the inorganic work-function-matching layer and is then the penultimate layer of the electrode. However, it is possible to insert, between the buffer layer and the inorganic work-function-matching layer, a layer which is less resistive than the buffer layer (metal layer, for example made of Ti, and the like) and which has a thickness of less than 5 nm, indeed even of less than or equal to 3 nm or 1 nm.

The buffer layer and the work-function-matching layer can be of the same nature but with a distinct degree of oxidation and/or a distinct degree of doping, in particular in order to adjust their electrical properties.

Preferably, the buffer layer and the work-function-matching layer are not of the same nature and typically differ in at least one element (metal, and the like) and/or in a type of doping, in order to adjust their electrical properties.

The lower the sheet resistance of the electrode (which is preferable in particular for electrode surface areas of at least 5 cm² by 5 cm²), the more sensitive the device is to defects and thus the more useful is the buffer layer. This is because, as the sheet resistance of an electrode is reduced, the region exhibiting a fall in voltage around a point defect will be increasingly large, resulting in an increasingly large black spot when the OLED is in operation.

The sheet resistance is preferably measured by a contactless inductive method, for example using a Nagy device having the reference SRM-12 on a sample with minimum dimensions of 10×10 cm².

The surface resistivity is defined as the electrical resistance experienced by a current which has passed through the layer perpendicularly to the surface planes of the layer, for a given unit of surface area.

In the context of the present invention, the resistivities are given at atmospheric pressure and at a temperature of 25° C.

The term “essentially inorganic layer” is understood to mean, according to the invention, a predominantly inorganic layer, indeed even a layer which is preferably inorganic to at least 90%.

In the present invention, mention is made of an underlying layer “x” or of a layer “x” under another layer “y”; this naturally implies that the layer “x” is closer to the substrate than the layer “y”.

It should be understood, by “layer” within the meaning of the present invention, that there may be one layer made of a single material (monolayer) or several layers (multilayer), each made of a different material.

Within the meaning of the present invention, the expression “based on” is to be understood, in a usual way, as a layer predominantly comprising the material involved, that is to say comprising at least 50% by weight of this material.

In the present invention, the anode is the lower electrode, thus the electrode closest to the substrate, and the cathode is the upper electrode, thus the electrode furthest from the substrate. The invention relates to the anode and/or the cathode.

Preferably, the surface resistivity of the buffer layer is within a range from 10⁻⁴ to 1 Ω·cm², indeed even from 10⁻² to 1 Ω·cm², in order to effectively limit the current passing through a point defect of short circuit type connecting the anode and the cathode, without, however, significantly increasing the operating voltage of the OLED.

The total number of conduction defects present on an OLED is strongly dependent on the degree of technological development used to prepare the OLED. Preferably, it is advisable to adjust the surface resistivity of the buffer layer to the amount of defects present on the OLED. To this end, the ranges of surface resistivity values which are preferred as a function of the fraction of surface area of the OLED exhibiting a short circuit with respect to the total active surface area of the OLED are illustrated in the following table 1. The lower and upper limits are chosen so as to reduce the maximum efficiency of the OLED by less than 3%. The basis is taken to be a surface resistivity of the OLED of 35 ohm·cm² at 1000 cd/m².

TABLE 1

| Defective | | | |
|---|---|---|---|
| surface area | Surface | Minimum surface | Maximum surface |
| (anode/cathode | resistivity of | resistivity of | resistivity of |
| short circuit)/ | the OLED at | the buffer | the buffer |
| total surface | 1000 cd/m² | layer | layer |
| area ratio | [ohm · cm²] | [ohm · cm²] | [ohm · cm²] |
| 1.00E−09 | 35 | 1.6E−06 | 1.0E+00 |
| 1.00E−08 | 35 | 1.6E−05 | 1.0E+00 |
| 1.00E−07 | 35 | 1.6E−04 | 1.0E+00 |
| 1.00E−06 | 35 | 1.6E−36 | 1.0E+00 |
| 1.00E−05 | 35 | 1.6E−02 | 1.0E+00 |

The buffer layer is preferably a monolayer.

Very particularly, the buffer layer preferably has a thickness of at most 150 nm, of at most 80 nm; more advantageously, this thickness is at most 60 nm, indeed even 40 nm. Preferably, the buffer layer has a thickness of at least 3 nm, preferably 5 or 7 nm.

Preferably, the buffer layer is amorphous, in order to limit the roughness of the stack.

The surface of the work-function-matching layer can have, in particular for this amorphous buffer layer, an RMS (otherwise known as Rq) roughness of less than or equal to 10 nm, preferably of less than or equal to 5 nm, more preferably still of less than or equal to 1.5 nm. The R.M.S. roughness means Root Mean Square roughness. It is a measurement which consists in measuring the value of the standard deviation of the roughness. This R.M.S. roughness, in practical terms, thus quantifies, as mean, the height of the roughness peaks and hollows, with respect to the mean height. Thus, an R.M.S. roughness of 2 nm means a double peak amplitude.

It can be measured by atomic force microscopy. The measurement is generally carried out over a square micrometer by atomic force microscopy.

Preferably, the buffer layer is based on one or more metal oxides, the metal part of which is preferably selected from at least one of the following elements: tin, zinc and tantalum, in particular SnₓZn_{y}O_{z} and Ta₂O₅, or a layer of vanadium oxide VOₓ.

This buffer layer based on one or more metal oxides is preferably not doped or is doped to less than 5%, indeed even than 2%, in order to adjust these electrical properties.

The metal oxide SnₓZn_{y}O_{z} is advantageously chosen from those for which the relative proportions of Sn with respect to the Zn are such that the ratio y/x varies from 1 to 2 and mention may be made, by way of example, of the following oxides stoichiometric in oxygen: SnZnO₃ and SnZn₂O₄. In the context of the invention, such oxides (SnₓZn_{y}O_{z}: y/x varies from 1 to 2) are chosen without distinction from oxides which are stoichiometric, substoichiometric or superstoichio-metric in oxygen.

The vanadium oxide is, for example, deposited with a V₂O₅ target by radiofrequency magnetron sputtering under an argon atmosphere typically exhibits a resistivity of approximately 10⁵ Ω·cm. Thus, with a thickness of 30 nm, its surface resistivity is 0.3 Ω·cm².

In another embodiment, the buffer layer is based on an inorganic nitride or on an inorganic oxynitride, in particular sufficiently doped and/or supernitrided and/or overoxidized in order to adjust the electrical properties. For example, the choice is made of silicon nitride or a nitride of semiconductor(s), such as gallium nitride, which is preferably doped, in particular with silicon, or aluminum nitride, which is preferably doped, in particular with silicon.

The surface area of the buffer layer is preferably less than or equal to that of the work-function-matching layer, that is to say that the surface area of the output underlayer represents at least 50% of the surface area of the output layer. Preferably, the surface area of the output underlayer represents at least 70%, advantageously 90%, indeed even more than 99%, of the surface area of the output layer.

Preferably, the buffer layer is present under the work-function-matching layer in the regions where the spikes have a particularly harmful impact on the operation of the OLED. The buffer layer is advantageously deposited at the periphery on the stack of the layers deposited beforehand on the substrate.

In the present invention, when the electrode is the anode, the work-function-matching layer is used for the injection of holes, with a work function which is sufficiently high, that is to say with at least 4.5 eV, preferably at least 5 eV.

In the present invention, when the electrode is the cathode, the work-function-matching layer is used for the injection of electrons, with a work function which is sufficiently low, that is to say less than 3.5 eV, preferably of less than 3 eV.

Preferably, the work-function-matching layer can exhibit a sheet resistance at least 40 times greater, indeed even at least 80 times greater or even 100 times greater, than the sheet resistance of the electrode (or of the coating).

Preferably, the work-function-matching layer can be based on transparent conductive oxide(s), preferably based on an indium oxide and on at least one oxide of an element chosen from tin, zinc and gallium.

Such metal oxides are normally named as follows:
IZO is used when it concerns a layer based on a mixed oxide of indium and zinc;
ITZO is used when it concerns a layer based on oxide of indium, tin and zinc; and
IGZO is used when it concerns a layer based on oxide of indium, zinc and gallium.

The work-function-matching layer can very particularly be a mixed oxide of indium and tin (ITO), with a thickness preferably of less than or equal to 50 nm, indeed even of less than or equal to 30 nm, indeed even of less than or equal to 10 nm. The sheet resistance is preferably greater than or equal to 100 Ω/square, 200 Ω/square, or even 500 Ω/square, 1000 Ω/square.

Its resistivity is preferably chosen greater than or equal to 10⁻³ Ω·cm. The resistivity of a conventional ITO produced without heat treatment is approximately 5×10⁻⁴ Ω·cm, i.e., for a thickness of 30 nm, a sheet resistance of 160Ω·

Preferably, in this form, the sheet resistance of the electrode (or of the coating, in particular anode) is less than or equal to 10 Ω/square, indeed even less than or equal to 7 Ω/square or even less than or equal to 5 Ω/square.

The work-function-matching layer can also be a molybdenum oxide MOₓ. The molybdenum oxide is, for example, deposited with an MoO₃ target by radiofrequency magnetron sputtering under an argon atmosphere typically exhibits a resistivity of approximately 10⁻² Ω·cm. Thus, with a thickness of 30 nm, its sheet resistance is 4000 Ω/square.

The electrode can form a transparent lower electrode, which is an anode, exhibits a sheet resistance of less than 20 Ω/square, preferably less than 10 Ω/square, indeed even less than 5 Ω/square.

Preferably, in a first embodiment, when the electrode according to the invention is an anode, in particular a transparent anode, the electrically conducting coating comprises (mainly) a thin layer based on a transparent conductive oxide (TCO) with a thickness of at least 80 nm and less than 250 nm. Advantageously, it is any one of the following TCOs: ITO, IZO, IGZO or ITZO.

Preferably, in a second embodiment of the anode, from the perspective of an anode with a lower sheet resistance, at reduced cost, the electrically conducting coating comprises at least one metal layer between two thin layers, which metal layer is based on a pure material chosen from silver, gold, copper or aluminum or a material which is optionally doped, or else alloyed, with at least one of the following elements: Ag, Au, Al, Pt, Cu, Zn, In, Si, Zr, Mo, Ni, Cr, Mg, Mn, Co, Sn or Pd. Mention may be made, for example, of silver doped with palladium or a gold/copper alloy or a silver/gold alloy.

The choice is preferably made of a layer based on silver (pure or doped or alloyed) for its conductivity and its transparency.

The electrically conducting coating can comprise several silver-comprising metal layers, each between at least two layers.

Preferably, the physical thickness of the or of each silver layer ranges from 6 to 20 nm. In this range of thicknesses, the electrode remains transparent.

Preferably, the electrically conducting coating with the metal layer or layers exhibits one or more layers of ITO, IZO, IGZO or ITZO, indeed even based on indium, with a cumulative thickness (if appropriate) of less than 60 nm, indeed even 50 nm, indeed even 30 nm. It can be is in particular devoid of layer of ITO, IZO, IGZO or ITZO, indeed even based on indium.

Advantageously, the electrode chosen anode according to the invention can exhibit one or the following characteristics:
a sheet resistance of less than or equal to 10 Ω/square for a functional layer thickness starting from 6 nm, preferably of less than or equal to 5 Ω/square for a functional metal layer thickness starting from 10 nm, preferably combined with a light transmission T_{L} of greater than or equal to 70%, more preferably still of greater than or equal to 80%, which renders particularly satisfactory its use as transparent electrode,
a sheet resistance of less than or equal to 1 Ω/square for a functional layer thickness starting from 50 nm, preferably of less than or equal to 0.6 Ω/square, preferably combined with a light reflection R_{L} of greater than or equal to 70%, more preferably still of greater than or equal to 80%, which renders particularly satisfactory its use as reflecting electrode, a sheet resistance of less than or equal to 3 Ω/square for a functional layer thickness starting from 20 nm, preferably of less than or equal to 1.8 Ω/square, preferably combined with a T_{L} to R_{L} ratio between 0.1 and 0.7, which renders particularly satisfactory its use as semitransparent electrode.

In order in particular to prevent the oxidation of the silver and to weaken its properties of reflection in the visible region, the or each silver layer is thus generally inserted in a stack of layers. The or each thin silver-based layer can be positioned between two thin dielectric layers based on oxide or nitride (for example made of SnO₂ or Si₃N₄).

It is possible to deposit, on the silver layer, a very thin sacrificial layer (for example made of titanium or of an alloy of nickel and chromium), known as overblocker layer, intended to protect the silver layer in the case where the deposition of the subsequent layer is carried out in an oxidizing or nitriding atmosphere, and in the event of heat treatments resulting in migration of oxygen within the stack.

The silver layer can also be deposited on and in contact with a layer known as underblocker layer. The stack can thus comprise an overblocker layer and/or an underblocker layer framing the or each silver layer.

The blocker (underblocker and/or overblocker) layers can be based on a metal chosen from nickel, chromium, titanium, tantalum or niobium or on an alloy of these various metals. Mention may in particular be made of nickel/titanium alloys (in particular those comprising approximately 50% by weight of each metal) or nickel/chromium alloys (in particular those comprising 80% by weight of nickel and 20% by weight of chromium). The overblocker layer can also be composed of several superimposed layers, for example, moving away from the substrate, of titanium and then of a nickel alloy (in particular a nickel/chromium alloy), or vice versa. The various metals or alloys mentioned can also be partially oxidized and/or nitrided, in particular can exhibit a substoichiometry in oxygen (for example TiOₓ or NiCrOₓ).

These blocker (underblocker and/or overblocker) layers are very thin, normally with a thickness of less than 1 nm, in order not to affect the light transmission of the stack, and are capable of being partially oxidized during the heat treatment according to the invention. As indicated in the continuation of the text, the thickness of at least one blocker layer can be higher, so as to form an absorbent layer within the meaning of the invention. Generally, the blocker layers are sacrificial layers, capable of capturing the oxygen radiating from the atmosphere or from the substrate, thus preventing the silver layer from oxidizing.

Preferably, the or each silver layer is covered with an overblocker layer with a thickness of less than 1 nm, based on a metal chosen from nickel, chromium, titanium or niobium or on an alloy of these various metals; advantageously, the overblocker layer is made of titanium.

Preferably, immediately under the or each silver layer or under the optional underblocker layer(s), the electrically conducting stack of the electrode according to the invention comprises a layer, known as wetting layer, the role of which is to increase the wetting, the attaching of the silver layer and the nucleation of the silver. The zinc oxide, in particular doped with aluminum, has proved to be particularly advantageous in this regard.

The electrically conducting stack of the anode according to the invention preferably comprises, directly under the or each wetting layer, a smoothing layer, which is a partially, indeed even completely, amorphous mixed oxide (thus of very low roughness), the role of which is to promote the growth of the wetting layer according to preferred crystallographic orientation, which promotes the crystallization of the silver by epitaxy phenomena. The smoothing layer is preferably composed of a mixed oxide of at least two metals chosen from tin, zinc, indium, gallium and antimony. A preferred oxide is the oxide of tin and zinc, optionally doped with antimony.

The stack can comprise one or more silver layers. When several silver layers are present, the general architecture presented above can be repeated.

The electrode according to the invention can also be a cathode; in this case, the work-function-matching layer is advantageously from 2 to 20 nm in thickness.

The sheet resistance of a cathode can be less than 20 Ω/square, indeed even less than 15 Ω/square (if cathode transparent, fairly thin), indeed even less than 1.5 Ω/square (if cathode reflecting, thicker).

When the electrode according to the invention is a cathode, the electrically conducting coating is advantageously a layer of aluminum or silver with a thickness of 80 to 200 nm, preferably of 90 to 180 nm, indeed even of 100 to 160 nm, in order to be reflecting; otherwise, with a thickness of less than or equal to 20 nm, indeed even of less than or equal to 15 nm, of less than or equal to 10 nm, in order to be transparent, or alternatively be a transparent conductive oxide as already described (ITO, and the like).

When the electrode according to the invention is a cathode, the work-function-matching layer can be made of LiF with a thickness of less than 10 nm and preferably of greater than 2 nm.

The substrate is preferably made of glass or of polymeric organic material. It is preferably transparent and colorless (it is then a clear or extra clear glass) or colored, for example blue, gray or bronze. The glass is preferably of soda-lime-silica type but it can also be a glass of borosilicate or aluminoborosilicate type. The preferred polymeric organic materials are polycarbonate, polymethyl methacrylate, polyethylene terephthalate (PET), polyethylene naphthalate (PEN) or also fluoropolymers, such as ethylene/tetrafluoroethylene (ETFE). The substrate advantageously exhibits at least one dimension of greater than or equal to 20 cm, indeed even 35 cm and even 50 cm. The thickness of the substrate generally varies between 0.025 mm and 19 mm, preferably between 0.4 and 6 mm, advantageously between 0.7 and 2.1 mm, for a glass substrate and preferably between 0.025 and 0.4 mm, advantageously between 0.075 and 0.125 mm, for a polymer substrate. The substrate can be flat or curved, indeed even flexible.

The glass substrate is preferably of the float glass type, that is to say capable of having been obtained by a process consisting of pouring the molten glass onto a bath of molten tin (float bath). In this case, the layer to be treated can equally well be deposited on the “tin” face as on the “atmosphere” face of the substrate. “Atmosphere” and “tin” faces are understood to mean the faces of the substrate which have been respectively in contact with the atmosphere prevailing in the float bath and in contact with the molten tin. The tin face comprises a small superficial amount of tin which has diffused into the structure of the glass. It can also be obtained by rolling between two rolls, a technique which makes it possible in particular to print patterns at the surface of the glass.

Preferably, the substrate is a soda-lime-silica glass obtained by floating which is not coated with layers and which exhibits a light transmission of order of 90%, a light reflection of the order of 8% and an energy transmission of the order of 83%, for a thickness of 4 mm. The light and energy transmissions and reflections are as defined in the standard NF EN 410. Typical clear glasses are, for example sold under the name SGG Planilux by Saint-Gobain Glass France or under the name Planibel Clear by AGC Flat Glass Europe.

Preferably, a layer referred to as base layer, which is typically an oxide, such as an oxide of silicon (SfO₂) or tin, or preferably a nitride, advantageously a silicon nitride Si₃N₄, is provided directly on the substrate. Generally, the silicon nitride Si₃N₄ can be doped, for example with aluminum or boron, in order to facilitate its deposition by cathode sputtering techniques. The degree of doping (corresponding to the atomic percentage with respect to the amount of silicon) generally does not exceed 2%. The main role of this base layer is to protect the silver layer from chemical or mechanical attacks and also influence the optical properties, in particular in reflection, of the stack, by virtue of interference phenomena.

The base layer also confers many advantages on the lower electrode according to the invention. First, it is capable of being a barrier to the alkalines underlying the electrode. It protects the contact layer from any contamination (contamination Which can result in mechanical defects, such as delaminations); in addition, it preserves the electrical conductivity of the conducting layer. It also prevents the organic structure of an OLED device from being contaminated by alkalines, in fact considerably reducing the lifetime of the OLED.

The migration of the alkalines can occur during the manufacture of the device, resulting in a lack of reliability, and/or subsequently, reducing its lifetime.

The deposition of the stack on the substrate can be carried out by any type of process, in particular processes generating predominantly amorphous or nanocrystalline layers, such as the cathode sputtering process, in particular the magnetic-field-assisted cathode sputtering process (magnetron process), the plasma-enhanced chemical vapor deposition (PECVD) process, the vacuum evaporation process or the sol-gel process.

The stack is preferably deposited by cathode sputtering, in particular magnetic-field-assisted cathode sputtering, commonly referred to as magnetron process.

According to another aspect, the invention relates to an OLED device comprising:
a lower electrode, which is an anode,
an organic light-emitting system including an organic electron injection layer of the OLED and an organic hole injection layer of the OLED,
an upper electrode, which is a cathode,
the substrate carrying the anode as described above and/or the substrate carrying the cathode as described above.

Preferably, the OLED device of the invention comprises two electrodes, the anode and the cathode, as described above in the context of the present invention. The inventors have found that the presence of a buffer layer on the two electrodes of such a device reduces even more the visual impact of a conducting defect generated by a spike, in comparison with an analogous device but comprising only a single electrode according to the invention.

The buffer layers for the anode and the cathode can be identical or distinct, at least in the thickness.

The surface resistivity of the lighting OLED according to the invention is typically from 5 to 500 ohm·cm² at 1000 cd/m².

The surface resistivity of the buffer layer is preferably 10 times lower than, indeed even 100 times lower than, or equal to the surface resistivity of the OLED.

The OLEDs are generally divided into two main families according to the organic light-emitting component used.

If the light-emitting layers are small molecules, the term used is SM-OLED (Small Molecule Organic Light-Emitting Diodes). The organic light-emitting material of the thin layer is formed from evaporated molecules such as, for example, the Alq₃ complex (tris(8-hydroxy-quinoline)aluminum), DPVBi (4,4′-(diphenylvinyl-biphenyl)), DMQA (dimethylquinacridone) or DCM (4-(di-cyanomethylene)-2-methyl-6-(4-dimethylaminostyryl)-4H-pyran). The emissive layer can also, for example, be a layer of 4,4′,4″-tri(N-carbazolyl)triphenylamine (TCTA) doped with fac-tris(2-phenylpyridine)iridium [Ir (ppy)₃].

Generally, the structure of an SM-OLED consists of a stack of Hole Injection Layer (HIL), Hole Transporting Layer (HTL), emissive layer and Electron Transporting Layer (ETL).

An example of hole injection layer is copper phthalocyanine (CuPc); the hole transporting layer can, for example, be N,N′-bis(naphthalen-1-yl)-N,N′-bis(phenyl)benzidine (α-NPB).

The electron transporting layer can be composed of tris(8-hydroxyquinoline)aluminum (Alq₃) or bathophen-anthroline (BPhen); in this case, one of the electrodes can be a layer of Mg/Al or LiF/Al.

An exciton-blocking layer, for example based on BCP (2,9-dimethyl-4,7-diphenyl-1,10-phenanthroline), can also be present in the stack.

Examples of organic light-emitting stacks are, for example, described in the document U.S. Pat. No. 6,645,645.

If the organic light-emitting layers are polymers, the term PLED (Polymer Light Emitting Diodes) is used.

The organic light-emitting material of the thin layer is formed from CES polymers (PLEDs), such as, for example, PPV for poly(para-phenylene vinylene), PPP (poly(para-phenylene)), DO-PPP (poly(2-decyloxy-1,4-phenylene)), MEH-PPV (poly[2-(2′-ethylhexyloxy)-5-methoxy-1,4-phenylene vinylene]), CN-PPV (poly[2,5-bis(hexyloxy)-1,4-phenylene-(1-cyanovinylene)]) or the PDAFs (poly(dialkylfluorene)); the polymer layer is also combined with a layer which promotes the injection of the holes (HIL) consisting, for example, of PEDT/PSS (poly(3,4-ethylenedioxythiophene)/poly(4-styrenesulfo-nate)).

An example of PLED consists of a following stack:
a 50 nm layer of poly(2,4-ethylenedioxythiophene) doped with poly(styrenesulfonate) (PEDOT:PSS),
a 50 nm layer of phenyl-poly(p-phenylene vinylene) Ph-PPV.

In the latter case, one of the electrodes can be a Ca layer.

The device can form (alternative or additional choice) a decorative, architectural, or the like, lighting system or an indicating display panel—for example of the design, logo or alpha-numeric indication type, in particular an emergency exit panel.

The OLED device can be arranged in order to produce a uniform polychromatic light, in particular for homogeneous lighting, or in order to produce different light-emitting regions, of the same intensity or of different intensity.

Conversely, it is possible to look for a varied polychromatic lighting. The organic light-emitting system (OLED) produces a direct light region and another light-emitting region is obtained by extraction of the OLED radiation, which is guided by total reflection in the thickness of the chosen glass substrate.

In order to form this other light-emitting region, the extraction region can be adjacent to the OLED system or on the other side of the substrate. The extraction region or regions can be used, for example, to reinforce the lighting provided by the direct light region, in particular for lighting of architectural type, or also to indicate the light panel. The extraction region or regions are preferably in the form of strip(s) of light which is (or are) in particular uniform and preferably positioned at the periphery of one of the faces. These strips can, for example, form a very light-emitting frame.

The extraction is obtained by at least one of the following means positioned in the extraction region: a scattering layer, the substrate rendered scattering, in particular textured or rough.

When the electrodes and the organic structure of the OLED system are chosen to be transparent, an illuminating window can in particular be produced. The improvement in the illumination of the room is then not produced at the expense of the light transmission. In addition, by limiting the light reflection, in particular on the external side of the illuminating window, this also makes it possible to control the level of reflection, for example in order to observe the antidazzling standards in force for the facades of buildings.

More broadly, the device, in particular partially or entirely transparent, can be:
intended for a building, such as an external light-emitting glazing panel, an internal light-emitting partition or a (part of a) light-emitting glazed door, in particular a sliding door,
intended for a means of transport, such as a light-emitting roof, a (part of a) light-emitting side window, or an internal light-emitting partition of a vehicle traveling on land, on water or in the air (automobile, truck, train, aircraft, boat, and the like),
intended for street or professional furniture, such as a bus shelter panel, a wall of a display cabinet, of a jewelers display or of a shop window, a wall of a greenhouse or an illuminating tile,
intended for internal furnishings, a shelf or furniture element, a front face of an item of furniture, an illuminating tile, a ceiling light or lamp, an illuminating refrigerator shelf or an aquarium wall.

In order to form an illuminating mirror, the upper electrode can be reflecting.

The OLED can be used for the illumination of a bathroom wall or of a kitchen worktop, or can be a ceiling light or lamp.

The invention is illustrated with the help of the following nonlimiting implementational examples.

### EXAMPLES

A sheet of glass (substrate) or of plastic, such as PET, is coated with a stack of layers by cathode sputtering. The layers are deposited in the order of stacking starting from the substrate, with the respective thicknesses indicated as follows.

### Example 1

A substrate made of soda-lime-silica glass (0.7 mm) carries a lower anode-forming electrode composed of the following stack:
an electrically conducting coating: Si₃N₄ doped with aluminum (30 nm)/SnₓZn_{y}O_{z} doped with antimony Sb (5 nm)/ZnO doped with aluminum (5 nm)/Ag (8 nm)/Ti (<1 nm)/ZnO doped with aluminum (5 nm)/SnₓZn_{y}O_{z} doped with antimony Sb (60 nm)/ZnO doped with aluminum (5 nm)/Ag (8 nm)/Ti (<1 nm),
covered with a SnZn₂O₄ buffer layer (40 nm), preferably intrinsic (nondoped), which buffer layer is amorphous,
and terminated by a work-function-matching layer made of ITO (10 nm).

### Example 2

A substrate made of soda-lime-silica glass (0.7 nm) carries a lower anode-forming electrode composed of the following stack:
an electrically conducting coating: SnₓZn_{y}O_{z} doped with antimony Sb (45 nm)/ZnO doped with aluminum (5 nm)/Ag (8 nm)/Ti (<1 nm)/ZnO doped with aluminum (5 nm)/SnₓZn_{y}O_{z} doped with antimony Sb (75 nm)/ZnO doped with aluminum (5 nm)/Ag (8 nm)/Ti (<1 nm),
covered with a Ta₂O₅ buffer layer (20 nm),
and terminated by a work-function-matching layer made of ITO (25 nm).

### Example 3

A substrate made of soda-lime-silica glass (0.7 mm) carries a lower anode-forming electrode composed of the following stack:
an electrically conducting coating: SnₓZn_{y}O_{z} (30 nm) doped with antimony Sb/ZnO (5 nm)/Ag (10 nm)/Ti (<1 nm)/ZnO doped with aluminum (5 nm)/ SnₓZn_{y}O_{z} (68 nm)/ZnO doped with aluminum (5 nm)/Ag (10 nm)/Ti (<1 nm),
covered with an intrinsic ZnO buffer layer (50 nm),
and terminated by a work-function-matching layer made of ITO (10 nm).

### Example 4

A substrate made of soda-lime-silica glass (4 mm) carries a lower anode-forming electrode composed of the following stack:
an electrically conducting coating: SiO₂ (10 nm)/ITO (200 nm),
covered with an SnZn₂O₄ buffer layer (20 nm),
and terminated by a work-function-matching layer made of ITO (10 nm).

In an alternative 4a, this electrically conducting coating is annealed at 350° C. for 30 min.

The electrical, transparency and roughness properties of these examples are shown in the following table.

TABLE 2

| | | | Sheet | | RMS |
|---|---|---|---|---|---|
| | Sheet | Sheet | resistance | | roughness |
| | resistance | resistance | work-function- | | parameter |
| Anode | coating | anode | matching layer | LT | of the |
| examples | Ω/square | Ω/square | Ω/square | (%) | anode |
| 1 | 3 | 3 | 1700 | 80 | <1.5 nm |
| 2 | 3 | 3 | 680 | 79 | <1.5 nm |
| 3 | 2.7 | 2.7 | 1700 | 78 | <1.5 nm |
| 4 | 20 | 20 | 1700 | 80 | <3 nm |
| 4a | 10 | 10 | 1700 | 82 | <5 nm |

The conditions for deposition by magnetic-field-assisted cathode sputtering (magnetron sputtering) for each of the layers underlying the buffer layer are as follows:
the layers based on Si₃N₄:Al are deposited by reactive sputtering using a silicon target doped with aluminum, under a pressure of 0.25 Pa in an argon/nitrogen atmosphere, fed in pulsed fashion,
the layers based on SnZn:SbOₓ are deposited by reactive sputtering using a target of zinc and tin doped with antimony comprising, by weight, 65% of Sn, 34% of Zn and 1% of Sb, under a pressure of 0.2 Pa and in an argon/oxygen atmosphere, fed in pulsed fashion,
the silver-base layers are deposited using a silver target, under a pressure of 0.8 Pa in an atmosphere of pure argon, fed in pulsed fashion,
the Ti layers are deposited using a titanium target, under a pressure of 0.8 Pa in an atmosphere of pure argon, fed in pulsed fashion,
the layers based on ZnO:Al are deposited by reactive sputtering using an aluminum-doped zinc target, under a pressure of 0.2 Pa and in an argon/oxygen atmosphere, fed in pulsed fashion.

The surface resistivity of the buffer layer based on metal oxide(s) depends on the nature of the oxides, on the optional doping, on the degree of oxidation and on the deposition process and is proportional to the thickness. For example, a conventional TCO layer of zinc oxide, in particular doped, especially with aluminum, for chemical stability, is too conducting. Consequently, in order to form a buffer layer, the overoxidation is sufficiently overdone and/or the thickness is increased.

The intrinsic ZnO buffer layer is deposited by reactive sputtering using a zinc target, under a pressure of 0.2 Pa and in an argon/oxygen atmosphere, preferably fed in radiofrequency fashion, for a layer with fewer oxygen vacancies and thus less conducting.

The buffer layers based on SnZn₂O₄ are deposited by reactive sputtering using a target of zinc and tin, under a pressure of 0.2 Pa and in an argon/oxygen atmosphere, fed in pulsed fashion.

The ITO work-function-matching layers are deposited using a flat target comprising 90% of indium in an atmosphere of pure argon, under a pressure of 4 mbar at a power of 1 kW. A resistivity of 1.7×10⁻³ Ω·cm and thus a sheet resistance of 1700 Ω/square are thus obtained.

The electrically conducting properties of the work-function-matching ITO are thus deliberately degraded in order to limit the lateral conductivity with respect to that of the electrically conducting coating.

The ITO layer of the conductive coating of example 4 is for its part conventional: it is deposited using a flat target comprising 90% indium in an atmosphere of pure argon, under a pressure of 1.5 mbar at a power of 1 kW. A conventional resistivity of 4×10⁻⁴ Ω·cm and thus a sheet resistance of 20⁻square are then obtained. The SiO₂ layer does not have an effect on the electrical conduction.

Comparative Tests Between an OLED According to the Invention and OLEDs of the State of the Art

In order to demonstrate the effectiveness of the novel lower electrode, comparative tests were carried out between the electrode of example 1 and a comparative electrode as presented in table 1 of the application of the prior art and exhibiting, on a substrate made of soda-lime-silica glass (0.7 mm), the following stack:

Si₃N₄ doped with aluminum (30 nm)/SnₓZn_{y}O_{z} doped with antimony Sb (5 nm)/ZnO doped with aluminum (5 nm)/Ag (8 nm)/Ti (<1 nm)/ZnO doped with aluminum (5 nm)/SnₓZn_{y}O_{z} doped with antimony Sb (60 nm)/ZnO doped with aluminum (5 nm)/Ag (8 nm)/Ti (<1 nm)/ITO (20 nm).

The electrode of example 1 and the comparative electrode are each respectively used to manufacture an OLED as follows: the procedure is carried out so as to obtain a lighting block, the greatest surface of which forms a square with a side length of 2 cm and which is light-emitting when the diode in operation is observed via the substrate.

In order to manufacture the OLED of type 1 (from example 1) and the comparative OLED respectively, the procedure is as follows: a stack of organic layers is deposited by vacuum evaporation during the same deposition on the electrode of example 1 and on the comparative electrode, which stack is formed, in order, of an organic hole injection layer of 10 nm of copper phthalocyanine (CuPc) and of a hole transporting layer of 40 nm of N,N′-bis(naphthalen-1-yl)-N,N′-bis(phenyl)-benzidine (α-NPB). The light-emitting layer is subsequently deposited by coevaporation of the green luminescent component fac-tris(2-phenylpyridine)iridium (Ir(ppy)₃) doped at 8% in a CBP matrix. An exciton-blocking layer of 10 nm of BCP (2,9-dimethyl-4,7-diphenyl-1,10-phenanthroline) is subsequently deposited, followed by 40 nm of Alq₃ (tris(8-hydroxy-quinoline)aluminum(III)), which acts as electron transporting layer. The thickness of the organic system is typically 30 nm.

Finally, the conventional cathode is deposited by vacuum evaporation and is composed of 1 nm of LiF, followed by 100 nm of Al.

A series of 10 OLEDs of type 1 and a series of 10 comparative OLEDs were manufactured, each of which is connected to a current-controlled electrical supply in order to subject them to lighting tests.

The operating voltage is of the order of 5 V and the current density of 1 mA/cm².

In operation, a decrease in the surface area of the black regions of the OLED of type 1 of at least 30% and which can range up to 80% is observed, with respect to the mean value of the black regions visually detected on the comparative OLEDs.

In the presence of micron-scale conduction defects, in contrast to the situation without buffer layer, the voltage remains constant over virtually the entire surface area of the OLED and the fall in voltage occurs this time only at a micro-scale distance from the center of the defect, thus reducing the non-illuminating surface area of the OLED.

Although the buffer layer is not the last placed at the top of the electrode, the buffer layer effectively limits the impact of the defect electrically connecting the anode and the cathode.

The surface resistivity of the buffer layer cannot arbitrarily be chosen to be high as excessively great surface resistivity would result in ohmic losses as the current passes through this layer, bringing about a fall in the overall efficiency of the system. Thus, it is useful for the surface resistivity of the buffer layer to be negligible (preferably 10 times lower, indeed even 100 times lower) in the face of the OLED surface resistivity.

The minimum surface resistivity of the buffer layer is determined by the ratio of defective surface area to the total active surface area of the OLED, as already indicated in table 1.

At the OLED/electrode with the buffer layer (anode or cathode) interface, the fall in potential is clear cut, which allows the potential to remain at its maximum value over a maximum OLED surface area. On the other hand, at the OLED/electrode without the buffer layer interface, the fall in potential is slower, which can result in a gradual decrease in the brilliance over dimensions detectable to the naked eye. This result shows that it is advantageous to use a buffer layer on each of the electrodes in order to reduce the visual impact of a conduction defect even more.

Thus, the following cathode according to the invention is proposed:
a work-function-matching layer made of LiF, with a thickness of less than 10 nm,
a reflecting metal layer made of aluminum with a thickness of between 80 and 200 nm, preferably between 90 and 180 nm, preferably between 100 and 160 nm,
and, between these two layers, a buffer layer exhibiting a surface resistivity of between 10⁻⁶ ohm·cm² and 1 ohm·cm², preferably between 10⁻⁴ ohm·cm² and 1 ohm·cm², preferably between 10⁻² ohm·cm² and 1 ohm·cm², a buffer layer, for example, made of SnZnO and deposited by electron beam (e-beam) evaporation.

In an example of reflecting cathode according to the invention, the following is chosen:
a work-function-matching layer made of LiF with a sheet resistance of greater than 100 Ω/square, deposited by evaporation in order not to detrimentally affect the organic surface, with a thickness of less than 10 nm, in particular of 5 nm (preferably at 1 or 2 nm, in order to protect the underlying organic layers from the subsequent magnetron depositions),
a 40 nm buffer layer made of SnZn₂O₄, deposited by magnetron sputtering as already indicated for the anode,
a conductive coating: 100 nm of aluminum deposited by magnetron sputtering with a sheet resistance of 0.3 Ω/square.

In an example of transparent cathode according to the invention (top emission and bottom emission OLED), the following is chosen:
a work-function-matching layer made of LiF with a sheet resistance of greater than 100 Ω/square, deposited by evaporation in order not to detrimentally affect the organic surface, with a thickness of less than 10 nm, in particular of 5 nm,
a 40 nm buffer layer made of SnZn₂O₄, deposited by magnetron sputtering as already indicated,
a conductive coating: 10 nm of silver deposited by magnetron sputtering with a sheet resistance of 5 Ω/square.

1. A substrate carrying an electrode intended to form the anode or the cathode of an organic light-emitting diode (OLED) device, said electrode being based on an electrically conducting stack with a sheet resistance of less than 25 Ω/square comprising:
an electrically conducting coating of one or more thin layers forming at least 90% of the electrical conduction of the stack,
an essentially inorganic thin electrically conducting layer which is a work-function-matching layer, to be placed in contact with an organic layer for injection of the charges of the OLED, wherein the work-function-matching layer exhibits a sheet resistance at least 20 times greater than the sheet resistance of the electrically conducting coating with a thickness of at most 60 nm, and
between the electrically conducting coating and the work-function-matching layer, a thin buffer layer, which is essentially inorganic and which has a surface resistivity within a range from 10⁻⁶ to 1 Ω·cm².

2. The substrate carrying an electrode as claimed in claim 1, wherein the surface resistivity of the buffer layer is within a range from 10⁻⁴ to 1 Ω·cm².

3. The substrate carrying an electrode as claimed in claim 1, wherein the buffer layer has a thickness of at most 80 nm.

4. The substrate carrying an electrode as claimed in claim 1, wherein the buffer layer is amorphous.

5. The substrate carrying an electrode as claimed in claim 1, wherein the buffer layer is based on one or more metal oxides, the metal part of which is selected from at least one of the following elements: tin, zinc and tantalum.

6. The substrate carrying an electrode as claimed in claim 1, wherein the buffer layer is chosen from a layer of SnₓZn_{y}O_{z}, such that the y/x ratio varies from 1 to 2, a layer of Ta₂O₅ or a layer of vanadium oxide.

7. The substrate carrying an electrode as claimed in claim 1, wherein the buffer layer is based on an inorganic nitride or an inorganic oxynitride.

8. The substrate carrying an electrode as claimed in claim 1, wherein the work-function-matching layer exhibits a sheet resistance at least 40 times greater than the sheet resistance of the electrode.

9. The substrate carrying an electrode as claimed in claim 1, wherein the work-function-matching layer is based on one or more transparent conductive oxides.

10. The substrate carrying an electrode as claimed in claim 1, wherein the work-function-matching layer is a mixed oxide of indium and tin with a sheet resistance of greater than or equal to 500 Ω/square, and with a sheet resistance of the electrode which is less than or equal to 10 Ω/square.

11. The substrate carrying an electrode as claimed in claim 1, wherein the work-function-matching layer is a molybdenum oxide.

12. The substrate carrying an electrode as claimed in claim 1, wherein the electrode forming a lower electrode which is an anode exhibits a sheet resistance of less than 20 Ω/square.

13. The substrate carrying an electrode as claimed in claim 1, wherein, the electrode being an anode, the conductive coating comprises a thin layer based on a transparent conductive oxide with a thickness of at least 80 nm which is chosen from a layer based on a mixed oxide of indium and tin, on oxide of indium, tin and zinc indium and zinc, on mixed oxide of indium and zinc on oxide of indium, zinc and gallium.

14. The substrate carrying an electrode as claimed in claim 1, wherein, the electrode being an anode, the electrically conducting coating comprises at least one metal layer based on pure silver, alloyed silver or doped silver, between two thin layers.

15. The substrate carrying an electrode as claimed in claim 14, wherein, immediately under the metal layer of silver, the electrically conducting coating comprises a wetting layer based on zinc oxide.

16. The substrate carrying an electrode as claimed in claim 15, wherein, immediately under the wetting layer, the coating comprises a smoothing layer which is composed of a mixed oxide of at least two metals chosen from tin, zinc, indium, gallium and antimony.

17. The substrate carrying an electrode as claimed in claim 1, wherein the electrode is a cathode and the electrically conducting coating is a layer of aluminum or silver with a thickness of 100 to 200 nm.

18. The substrate carrying an electrode as claimed in claim 1, wherein the electrode is a cathode and the work-function-matching layer is made of LiF with a thickness of less than 10 nm.

19. The substrate carrying an electrode as claimed in claim 1, wherein the substrate is made of glass or of polymeric organic material.

20. A process for the manufacture of an electrode as claimed in claim 1, wherein the electrically conducting coating is deposited by magnetron cathode sputtering.

21. An organic light-emitting diode (OLED) device comprising, on a substrate, carrying in this order:
a lower electrode, which is an anode,
an organic light-emitting system including an organic electron injection layer of the OLED and an organic hole injection layer of the OLED,
an upper electrode, which is a cathode,
the substrate carrying the anode and/or the substrate carrying the cathode, as claimed in claim 1.

22. The organic light-emitting diode device as claimed in claim 1, wherein the organic light-emitting diode device forms one or more transparent and/or reflecting light-emitting surfaces of a decorative or architectural lighting system or an indicating display panel, the system or panel producing a uniform light or varied light-emitting regions.
